(19) United States
(12) Patent Application Publication
(10) Pub. No.: US 2015/0316814 A1
(43) Pub. Date: Nov. 5, 2015

(54) LIQUID-CRYSTAL DISPLAY PANEL, LIQUID-CRYSTAL DISPLAY, AND METHOD FOR MANUFACTURING LIQUID-CRYSTAL DISPLAY PANELS

(71) Applicant: SHARP KABUSHIKI KAISHA, Osaka-shi, Osaka (JP)

(72) Inventors: Hirohiko NISHIKI, Osaka (JP); Shinya KADONO, Osaka (JP); Yukimine SHIMADA, Osaka (JP)

(73) Assignee: SHARP KABUSHIKI KAISHA, Osaka (JP)

(21) Appl. No.: 14/651,350

(22) PCT Filed: Dec. 11, 2013
(86) PCT No.: PCT/JP2013/083198

§ 371 Date: Jun. 11, 2015

(30) Foreign Application Priority Data
Dec. 12, 2012 (JP) 2012-271388

(51) Int. Cl. G02F 1/1335; G02F 1/1368; H01L 27/12

(52) U.S. Cl. CPC G02F 1/133512; H01L 27/1259; G02F 1/1368; G02F 1/133615

(57) ABSTRACT

Provided is a liquid crystal display panel, including: a circuit substrate and an opposite substrate disposed to face each other; a liquid crystal layer sandwiched between the circuit substrate and the opposite substrate; a display region provided on a surface of the circuit substrate facing the liquid crystal layer and having at least a plurality of pixel electrodes; a peripheral region provided in a periphery of the display region and having at least a plurality of thin film transistors; a first light-shielding layer provided on a side of the opposite substrate so as to shield at least a region corresponding to the peripheral region from light; and a second light-shielding layer provided on a surface of the first substrate on a side opposite to the surface facing the liquid crystal layer so as to shield at least a region corresponding to the peripheral region from light.

### TECHNICAL FIELD

The present invention relates to a liquid crystal display panel, a liquid crystal display device, and a method of manufacturing a liquid crystal display panel.

This application claims priority based on Japanese Patent Application 2012-271388 filed in Japan on Dec. 12, 2012, the contents thereof are incorporated herein by reference.

### BACKGROUND ART

In recent years, there has been active development of liquid crystal display devices. Particularly dominant has been the development of liquid crystal display devices equipped with liquid crystal display panels employing an active matrix driving method. Specifically, this type of liquid crystal display panel includes a circuit substrate, an opposite substrate, and a liquid crystal layer sandwiched therebetween.

On a surface of the circuit substrate facing the liquid crystal layer, a plurality of pixel electrodes, each of which serves as a unit of image display, are arranged in a matrix. These form a display region for displaying images. In addition, a switching element such as a thin film transistor is connected to each pixel electrode. This switching element makes it possible to switch to and from the on/off state of the driving voltage applied to each pixel electrode.

Further, a peripheral circuit region is provided in a periphery of the display region of the circuit substrate (a peripheral circuit region). The peripheral circuit region includes a source driver, which is electrically connected to source bus lines, and a gate driver, which is electrically connected to gate bus lines. Along with the TFTs for the switching elements, TFTs and other components constituting the peripheral circuit regions are formed integrally (as a monolithic structure) on the circuit substrate of the liquid crystal display panel.

On the other hand, provided on a surface of the opposite substrate facing the liquid crystal layer are: a solid opposite electrode facing the plurality of pixel electrodes; and a black matrix layer that has a light-shielding property and that partitions the region corresponding to the pixel electrodes (a pixel region) into a grid.

Meanwhile, when the TFTs for the switching elements and the TFTs for the peripheral circuit region are illuminated with light, a photocurrent occurs due to generation of electron-hole pairs, leading to problems such as an increase in leakage current during an off time. Additionally, an increase in leakage current may cause a significant decrease in display quality in a liquid crystal display panel due to an occurrence of crosstalk or a decrease in contrast (see Patent Documents 1 to 4, for example).

For this reason, in a conventional liquid crystal display panel, a black matrix layer (light-shielding layer) is provided not only on the side of the opposite substrate to shield areas surrounding the pixel electrodes, but also in a region corresponding to the peripheral circuit region so as to block light entering the TFTs in the peripheral circuit region.

In addition, light may enter the liquid crystal display panel from regions other than the regions in which the black matrix layers (light-shielding layers) are provided. To solve such a problem, a proposal has been made to provide a light-shielding film above and below TFTs, so as to enhance the light-shielding effect on the TFTs (see Patent Document 5, for example).

However, providing a light-shielding film above and below the TFTs raises other problems such as imprecision in the alignment of the light-shielding films and a decrease in the aperture ratio.

Meanwhile, in the aforementioned liquid crystal display panel, when light from a backlight or the like disposed to face the circuit substrate illuminates the circuit substrate with light, light enters the TFTs provided in the peripheral circuit region from the circuit substrate side, thereby degrading the properties of the TFTs.

### RELATED ART DOCUMENTS

### Patent Documents

Patent Document 1: Japanese Patent Application Laid-Open Publication No. 2002-319679

Patent Document 2: Japanese Patent Application Laid-Open Publication No. 2004-053630

Patent Document 3: Japanese Patent Application Laid-Open Publication No. 2004-158518

Patent Document 4: Japanese Patent Application Laid-Open Publication No. 2004-179450

Patent Document 5: Japanese Patent Application Laid-Open Publication No. 2004-53630

### SUMMARY OF THE INVENTION

### Problems to be Solved by the Invention

The present invention has been prepared to solve the problems described above, and aims to provide a liquid crystal display panel, a liquid crystal display device, and a method of manufacturing a liquid crystal display panel capable of enhancing the light-shielding effect on the thin film transistors provided in the peripheral circuit region and providing, with good precision, the light-shielding layer for shielding the thin film transistors from light.

### Means for Solving the Problems

In order to achieve the objectives described above, the present invention has employed the following:

(1) A liquid crystal display panel according to an embodiment of the present invention includes: a first transparent substrate and a second transparent substrate facing each other; a liquid crystal layer sandwiched between the first transparent substrate and the second transparent substrate; a display region provided on a surface of the first transparent substrate facing the liquid crystal layer and having at least a plurality of pixel electrodes; a peripheral circuit region provided around the display region and having at least a plurality of thin film transistors; a first light-shielding layer provided on a side of the second substrate so as to shield at least a region corresponding to the peripheral circuit region from light; and a second light-shielding layer provided on a surface of the first substrate on a side opposite to the surface facing the liquid crystal layer so as to shield at least a region corresponding to the peripheral circuit region from light.

(2) In the liquid crystal display panel according to (1) above, the second light-shielding layer may be made of a photosensitive resin composition selectively provided in at least a region corresponding to the peripheral circuit region.

(3) In the liquid crystal display panel according to (1) above, the second light-shielding layer may be made of a photosensitive resin composition that covers the surface of the second substrate on the side opposite to the surface facing the liquid crystal layer and that is selectively decolorized in at least a region corresponding to the display region.

(4) In the liquid crystal display panel according to (1) above, the second light-shielding layer may be made of a photosensitive resin composition that covers the surface of the second substrate facing the liquid crystal layer and that is selectively colorized in at least a region corresponding to the peripheral circuit region.

(5) In the liquid crystal display panel according to any one of (1) to (4) above, thin film transistors respectively made of oxide semiconductors may be provided in the peripheral circuit region.

(6) A liquid crystal display device according to an embodiment of the present invention may include the liquid crystal display panel according to any one of (1) to (5) above; and a backlight that illuminates the liquid crystal display panel.

(7) In the liquid crystal display device according to (6) above, the backlight may be disposed on the side opposite to the surface of the first transparent substrate facing the liquid crystal layer.

(8) A method of manufacturing a liquid crystal display panel according to an embodiment of the present invention includes: preparing a liquid crystal display panel that includes a first transparent substrate and a second transparent substrate facing each other; a liquid crystal layer sandwiched between the first transparent substrate and the second transparent substrate; a display region provided on a surface of the first transparent substrate facing the liquid crystal layer and having at least a plurality of pixel electrodes; a peripheral circuit region provided around the display region and having at least a plurality of thin film transistors; a first light-shielding layer provided on a side of the second substrate so as to shield at least a region corresponding to the peripheral circuit region from light; and forming a second light-shielding layer provided on a side of the first substrate so as to shield at least a region corresponding to the peripheral circuit region from light, wherein the step of forming the second light-shielding layer further includes: forming a coating film of a photosensitive resin composition on a surface of the first substrate on a side opposite to the surface facing the liquid crystal layer; and patterning the coating film into a shape corresponding to the first light-shielding layer by exposing the coating film to light radiated from a side of the second transparent substrate.

(9) The method of manufacturing a liquid crystal display panel according to (8) above may further include selectively removing a portion of the coating film that has been patterned by exposure to light.

(10) In the method of manufacturing a liquid crystal display panel according to (8) above, a photosensitive resin composition may be used in which portions thereof exposed to light are decolorized.

(11) A method of manufacturing a liquid crystal display panel according to an embodiment of the present invention includes: preparing a liquid crystal display panel that includes a first transparent substrate and a second transparent substrate facing each other; a liquid crystal layer sandwiched between the first transparent substrate and the second transparent substrate; a display region provided on a surface of the first transparent substrate facing the liquid crystal layer and having at least a plurality of pixel electrodes; a peripheral circuit region provided around the display region and having at least a plurality of thin film transistors; a first light-shielding layer provided on a side of the second substrate so as to shield at least a region corresponding to the peripheral circuit region from light; and forming a second light-shielding layer provided on a side of the first substrate so as to shield at least a region corresponding to the peripheral circuit region from light, wherein the step of forming the second light-shielding layer further includes: forming a coating film of a photosensitive resin composition on a surface of the first substrate on a side opposite to the surface facing the liquid crystal layer; and patterning the coating film into a shape corresponding to the peripheral circuit region by exposing the coating film to light radiated from a side of first transparent substrate.

(12) In the method of manufacturing a liquid crystal display panel according to (11) above, a photosensitive resin composition may be used in which portions thereof exposed to light are decolorized.

(13) In the method of manufacturing a liquid crystal display panel according to any one of (8) to (12), thin film transistors respectively made of oxide semiconductors may be provided in the peripheral circuit region.

### Effects of the Invention

Thus, according to embodiments of the present invention, it is possible to provide a liquid crystal display panel, a liquid crystal display device, and a method of manufacturing a liquid crystal display panel that can enhance a light-shielding effect for thin film transistors provided in a peripheral circuit region and that can provide a light-shielding layer for shielding the thin film transistors from light with good precision.

### BRIEF DESCRIPTION OF THE DRAWINGS

FIG. 1 is a plan view showing a structure of a liquid crystal display panel.

FIG. 2 is a cross-sectional view of a display region of the liquid crystal display panel shown in FIG. 1.

FIG. 3 is a cross-sectional view of a peripheral region of the liquid crystal display panel shown in FIG. 1.

FIG. 4 is a cross-sectional view schematically showing a liquid crystal display panel according to Embodiment 1.

FIG. 5A is a first cross-sectional diagram for describing steps of manufacturing the liquid crystal display panel shown in FIG. 4.

FIG. 5B is a second cross-sectional diagram for describing steps of manufacturing the liquid crystal display panel shown in FIG. 4.

FIG. 5C is a third cross-sectional diagram for describing steps of manufacturing the liquid crystal display panel shown in FIG. 4.

FIG. 5D is a fourth cross-sectional diagram for describing steps of manufacturing the liquid crystal display panel shown in FIG. 4.

FIG. 6 is a cross-sectional view schematically showing a liquid crystal display panel according to Embodiment 2.

FIG. 7A is a first cross-sectional diagram for describing steps of manufacturing the liquid crystal display panel shown in FIG. 6.

FIG. 7B is a second cross-sectional diagram for describing steps of manufacturing the liquid crystal display panel shown in FIG. 6.

FIG. 7C is a third cross-sectional diagram for describing steps of manufacturing the liquid crystal display panel shown in FIG. 6.

FIG. 8 is a cross-sectional view schematically showing a liquid crystal display panel according to Embodiment 3.

FIG. 9A is a first cross-sectional diagram for describing steps of manufacturing the liquid crystal display panel shown in FIG. 8.

FIG. 9B is a second cross-sectional diagram for describing steps of manufacturing the liquid crystal display panel shown in FIG. 8.

FIG. 9C is a third cross-sectional diagram for describing steps of manufacturing the liquid crystal display panel shown in FIG. 8.

### DETAILED DESCRIPTION OF EMBODIMENTS

Embodiments of the present invention will be described with reference to diagrams. Note that different scales may be used in the following diagrams for the dimensions of certain components, so that the components are easy to see.

<Liquid Crystal Display Panel>

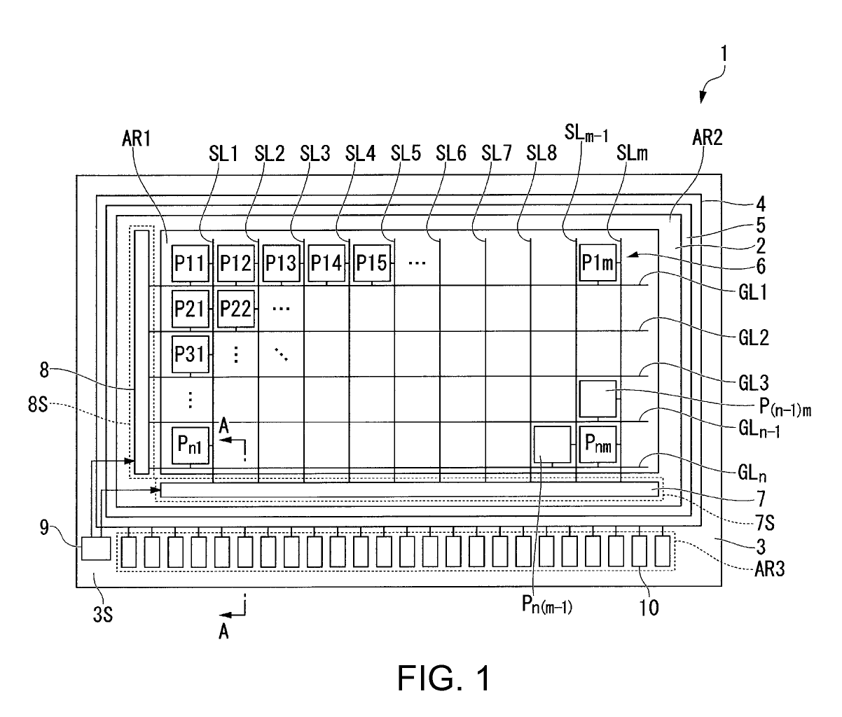

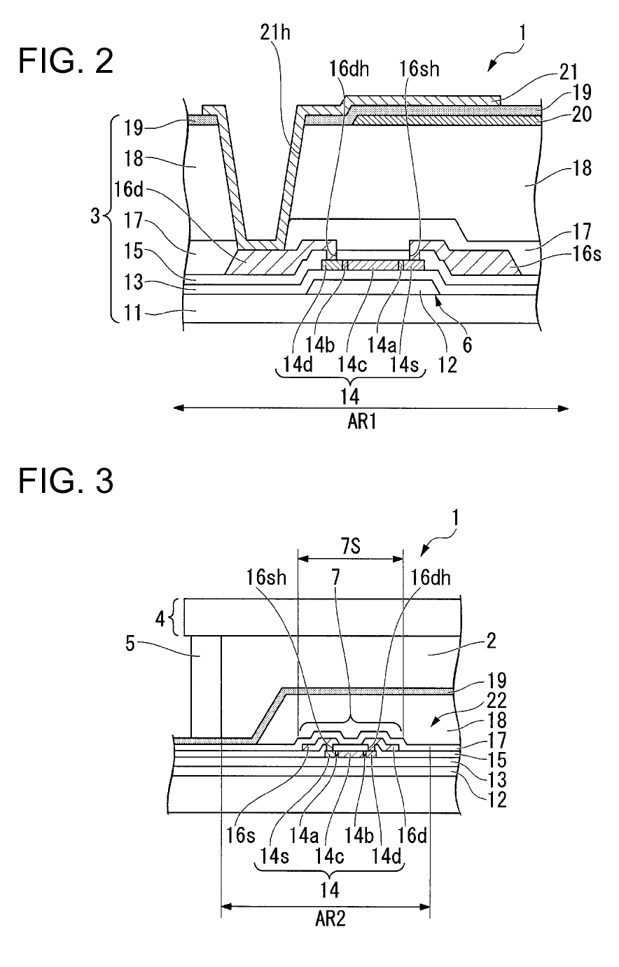

FIG. 1 is a plan view showing a liquid crystal display panel 1. FIG. 2 is a cross-sectional view of a display region AR1 of the liquid crystal display panel 1 shown in FIG. 1. FIG. 3 is a cross-sectional view of a peripheral region AP2 of the liquid crystal display panel 1 shown in FIG. 1 along the line A-A′.

As shown in FIGS. 1 and 2, the liquid crystal display panel 1 is structured such that a circuit substrate 3 (a first transparent substrate) and an opposite substrate 4 (a second transparent substrate) are disposed to face each other. The area between the substrates is sealed along the periphery by a sealing member 5, and liquid crystal is injected therebetween so that a liquid crystal layer 2 is held between the circuit substrate 3 and the opposite substrate 4.

Additionally, the liquid crystal display panel 1 according to the present embodiment displays images in an FFS (Fringe Field Switching) mode, for example, and liquid crystal with a positive dielectric anisotropy is used for the liquid crystal layer 2. Note that the display mode of the liquid crystal display panel 1 is not limited to the FFS mode; a TN (Twisted Nematic) mode, a VA (Vertical Alignment) mode, an STN (Super Twisted Nematic) mode, an IPS (In-Plane Switching) mode, or the like can also be used.

Provided on a surface of the circuit substrate 3 facing the liquid crystal layer 2 are: a display region AR1, which has a rectangular shape when seen from a direction normal to the circuit substrate 3 (hereinafter referred to as plan view); and a peripheral region AR2, which is found in a periphery of the display region AR1 and has a rectangular frame shape in plan view.

Provided in the display region AR1 of the circuit substrate 3 are: a plurality of source bus lines SL1 to SLm (hereinafter may collectively be referred to as source bus line(s) SL); a plurality of gate bus lines GL1 to GLn (hereinafter may collectively be referred to as gate bus line(s) GL); and a plurality of switching elements 6.

The plurality of source bus lines SL are disposed parallel to each other while extending in one direction (vertical direction in FIG. 1). The plurality of gate bus lines GL are disposed parallel to each other while extending in a direction perpendicular to the aforementioned one direction (horizontal direction in FIG. 1). Note that the plurality of source bus lines SL and the plurality of gate bus lines GL do not need to cross each other at right angles, and may cross each other at an angle other than 90°.

The display region AR1 of the circuit substrate 3 is partitioned into rectangular regions by the plurality of source bus lines SL and the plurality of gate bus lines GL arranged in a grid, each of such regions constituting a pixel. Therefore, in the display region AR1, a plurality of pixels P11 to Pnm (hereinafter may collectively be referred to as pixel(s) P) are arranged in a matrix. In addition, a pixel electrode 21 (not shown in FIG. 1), which serves as a unit of image display, is disposed in each of the pixels P.

The switching element 6 is constituted by a thin film transistor (TFT), for example, and is provided for each of the intersections of the plurality of source bus lines SL and the plurality of gate bus lines GL. In addition, the source bus line SL is electrically connected to the source of the switching element; the pixel electrode 21 is electrically connected to the drain of the switching element; and the gate bus line GL is electrically connected to the gate of the switching element.

In the peripheral region AR2 of the circuit substrate 3, a source driver 7 and a gate driver 8 are provided as a peripheral circuit region, as shown in FIGS. 1 and 3. The source driver 7 and the gate driver 8 include a plurality of second thin film transistors (TFTs) 22 (not shown in FIG. 1), which will be described later. In addition, the source driver 7 and the gate driver 8 are disposed on the inner side of the region enclosed by the sealing member 5.

The source driver 7 is disposed along a direction in which the plurality of source bus lines SL are lined up (hereinafter may be referred to as the horizontal line direction). Additionally, one end of each of the plurality of source bus lines SL is electrically connected to the source driver 7.

The gate driver 8 is disposed along a direction in which the gate bus lines GL are lined up (hereinafter may be referred to as the vertical line direction). Additionally, one end of each of the plurality of gate bus lines GL is electrically connected to the gate driver 8.

The size of the circuit substrate 3 in plan view is greater than the size of the opposite substrate 4 in plan view. The sealing member 5 is disposed along the periphery of the opposite substrate 4 in a rectangular frame shape in plan view. The circuit substrate 3 and the opposite substrate 4 are attached to each other by the sealing member 5 with a prescribed gap therebetween.

As a result, outside of the region surrounded by the sealing member 5 is formed a region 3S (hereinafter referred to as extending region), which is an area of the circuit substrate 3 extending out of the opposite substrate 4. A control circuit 9 and a plurality of terminals 10 are provided in the extending region 3S.

The control circuit 9 supplies control signals for displaying images to the source driver 7 and the gate driver 8. Specifically, control signals supplied to the source driver 7 include a source start pulse (SSP), a source shift clock (SSC) signal, a source output enable (SOE) signal, a polarity control signal (POL), and the like. On the other hand, control signals supplied to the gate driver 8 include a gate start pulse (GSP), a gate shift clock (GSC) signal, a gate output enable (GOE) signal, and the like.

The gate driver 8 supplies scanning signals sequentially to the gate bus lines GL1 to GLn in the order of GL1, GL2, GL3, and so forth, to GLn. In response to the scanning signals, each horizontal line of the switching 6 operates as a unit.

The source driver 7 converts the supplied image signals into analog image signals. For each horizontal interval in which scanning signals are supplied to each of the gate bus lines GL, the source driver 7 supplies image signals for a single horizontal line to the plurality of source bus lines SL1 to SLm.

The plurality of terminals 10 are arranged parallel to each other in a region AR3 (hereinafter referred to as terminal-forming region), which is aligned with the horizontal line direction. The plurality of terminals 10 are electrically connected to the source driver 7 and the gate driver 8.

As shown in FIGS. 2 and 3, the circuit substrate 3 is formed by a substrate (transparent substrate) 11 having a light-transmissive property such as a glass substrate, for example. On a surface of the transparent substrate 11 of the circuit substrate 3 that faces the liquid crystal layer 2, the TFTs 6 for the switching elements and the TFTs 22 for the peripheral circuit region are formed.

Note that the TFTs 6 provided for the switching elements in the display region AR1 shown in FIG. 2 and the TFTs 22 provided for the peripheral circuit region in the peripheral region AR2 shown in FIG. 3 have basically identical structures and are formed in the same steps. For this reason, identical portions will be given identical reference characters, and the TFTs 6 and 22 will be described together.

While the TFTs 6 and 22 in the present embodiment are of an n-channel type, p-channel type TFTs 6 and 22 are also acceptable. Additionally, while the TFTs 6 in the present embodiment are of a bottom-gate type, top-gate type TFTs 6 may also be used.

Each of the TFTs 6 and 22 includes: a gate electrode 12, which is constituted by a first conductive film; a gate insulating film 13; a semiconductor layer 14; and a source electrode 16s and a drain electrode 16d, which are constituted by a second conductive film.

The gate electrode 12 is formed on a transparent substrate 11. As a material for the gate electrode 12, a W (tungsten)/TaN (tantalum nitride) multilayer film, Mo (molybdenum), Ti (titanium), Al (aluminum), or the like can be used, for example. Note that the gate electrode 12 is constituted by a portion of the gate bus line GL.

The gate insulating film 13 is formed over the transparent substrate 11 so as to cover the gate electrode 12. As a material for the gate insulating film 13, an inorganic insulating material such as a silicon nitride film, a silicon oxide film, a silicon oxynitride film, a multilayer film thereof, or the like can be used, for example.

On the gate insulating film 13, a semiconductor layer 14 is formed so as to face the gate electrode 12. As a material for the semiconductor layer 14, IGZO (an In—Ga—Zn—O type semiconductor), which is an oxide constituted by indium, gallium, and zinc, can be used.

Note that the material for the semiconductor layer 14 is not limited to an oxide semiconductor such as IGZO or the like; semiconductors such as CGS (Continuous Grain Silicon), LPS (Low-temperature Poly-Silicon), α-Si (Amorphous Silicon), or the like can also be used, for example.

However, it is preferable that an oxide semiconductor such as IGZO be used as a material for the semiconductor layer 14 for the following reasons:

An oxide semiconductor has a higher mobility than α-Si. For this reason, a TFT using an oxide semiconductor is able to operate at a higher speed than a TFT using α-Si. In addition, an oxide semiconductor layer is formed in simpler steps than a polycrystalline silicon layer, and is therefore applicable to a device that requires a large area.

An oxide semiconductor layer can be formed in the following manner, for example. First, an IGZO film with a thickness between 30 nm and 300 nm is formed on an insulating film using a sputtering method. Next, a resist mask is formed using photolithography to cover a prescribed region of the IGZO film. Then, the area of the IGZO film not covered by the resist mask is removed by wet etching. Subsequently, the resist mask is removed. An oxide semiconductor layer is obtained in this manner.

In addition, other than IGZO, IZO (In—Zn—O type semiconductor), which is an oxide constituted by indium and zinc, ZTO (Zn—Ti—O type semiconductor), an oxide constituted by zinc and titanium, or the like can also be used as an oxide semiconductor, for example.

The semiconductor layer 14 includes: a channel region 14c, a first heavily doped region 14s, a second heavily doped region 14d, a first lightly doped region 14a, and a second lightly doped region 14b.

The channel region 14c functions as a channel region of the semiconductor layer 14. The first heavily doped region 14s functions as a source region of the semiconductor layer 14. The second heavily doped region 14d functions as a drain region of the semiconductor layer 14.

The first heavily doped region 14s and the second heavily doped region 14d are spaced apart so as to sandwich the channel region 14c therebetween. The first heavily doped region 14s is provided closer to the source electrode 16s than the channel region 14c. The second heavily doped region 14d is provided closer to the drain electrode 16d than the channel region 14c.

In the channel region 14c, p-type impurities such as B (boron) are doped.

The first heavily doped region 14s and the second heavily doped region 14d both contain n-type impurities in higher concentrations than the lightly doped regions. For this reason, the concentrations of n-type carriers in the first heavily doped region 14s and the second heavily doped region 14d are higher than in the lightly doped regions.

The first lightly doped region 14a is provided between the channel region 14c and the first heavily doped region 14s. The second lightly doped region 14b is provided between the channel region 14c and the second heavily doped region 14d.

The first lightly doped region 14a and the second lightly doped region 14b both contain n-type impurities in lower concentrations than the heavily doped regions. For this reason, the concentrations of n-type carriers in the first lightly doped region 14a and the second lightly doped region 14b are lower than in the heavily doped regions.

Thus, the first heavily doped region 14s and the first lightly doped region 14a, and the second heavily doped region 14d and the second lightly doped region 14b respectively form LDD (Lightly Doped Drain) structures.

A first interlayer insulating film 15 is formed over the gate insulating film 13 so as to cover the semiconductor layer 14. As a material for the first interlayer insulating film 15, an inorganic insulating material similar to the material for the gate insulating film 13 described above can be used.

A source electrode 16s and a drain electrode 16d are formed on the first interlayer insulating film 15. The source electrode 16s is connected to the first heavily doped region 14s of the semiconductor layer 14 via a contact hole 16sh, which passes through the first interlayer insulating film 15. The drain electrode 16d is connected to the second heavily doped region 14d of the semiconductor layer 14 via a contact hole 16dh, which passes through the first interlayer insulating film 15. As a material for the source electrode 16s and the drain electrode 16d, a conductive material similar to the material for the gate electrode 12 described above can be used.

A first passivation film 17 is formed over the first interlayer insulating film 15 so as to cover the source electrode 16s and the drain electrode 16d. As a material for the first passivation film 17, an inorganic material similar to the material for the gate insulating film 13 described above can be used.

On the first passivation film 17, a second interlayer insulating film 18 (organic insulating film) is formed. As a material for the second interlayer insulating film 18, an organic insulating material such as polyimide, polyamide, acryl, polyimide-amide, benzocyclobutene, or the like can be used, for example.

Formed on the second interlayer insulating film 18 is a common electrode 20 (a first transparent electrode), which is constituted by a third conductive film. As a material for the common electrode 20, a transparent conductive material such as ITO (Indium Tin Oxide), IZO (Indium Zinc Oxide), or the like can be used, for example.

Over the second interlayer insulating film 18, a second passivation film 19 (inorganic insulating film) is formed so as to cover the common electrode 20. As a material for the second passivation film 19, an inorganic material similar to the material for the first passivation film 17 described above can be used.

Formed on the second passivation film 19 is a pixel electrode 21 (second transparent electrode), which is constituted by a fourth conductive film. As a material for the pixel electrode 21, a transparent conductive material similar to the material for the common electrode 20 described above can be used.

Formed in the display region AR1 is a transparent capacitive structure, which is constituted by the common electrode 20 and the pixel electrode 21 disposed to face each other with the second passivation film 19 therebetween. In the display region AR1, the second passivation film 19 functions as an inter-electrode insulating film between the common electrode 20 and the pixel electrode 21.

The pixel electrode 21 is connected to the drain electrode 16d via the contact hole 21h, which passes through the first passivation film 17, the second interlayer insulating film 18, and the second passivation film 19. The pixel electrode 21 is connected to the second heavily doped region 14d of the semiconductor layer 14 via the drain electrode 16d, which acts as a relaying electrode.

In such a configuration, when scanning signals are supplied via the gate bus line GL and the first TFT 6 turns on, the image signals supplied to the source electrode 16s via the source bus line SL is supplied to the pixel electrode 21 via the semiconductor layer 14 and the drain electrode 16d.

Over the second passivation film 19, an alignment film (not shown in diagrams) is formed so as to cover the pixel electrode 21. The alignment film has an alignment-regulating capability to horizontally orient liquid crystal of the aforementioned liquid crystal layer 2.

Meanwhile, the opposite substrate 4 is formed using a substrate with a light-transmissive property (transparent substrate), such as a glass substrate. Formed on a surface of the transparent substrate of the opposite substrate 4 that faces the liquid crystal layer 2 are (omitted from diagrams): a solid opposite electrode facing the aforementioned plurality of pixel electrodes 21; a black matrix layer, which has a light-shielding property and which partitions the region corresponding to pixel electrodes 21 (pixel region P) into a grid; a color filter layer embedded on the inside of the region partitioned by the black matrix layer 12; an alignment film, which horizontally orients liquid crystal constituting the liquid crystal layer 2; and the like.

### Embodiment 1

### Liquid Crystal Display Panel

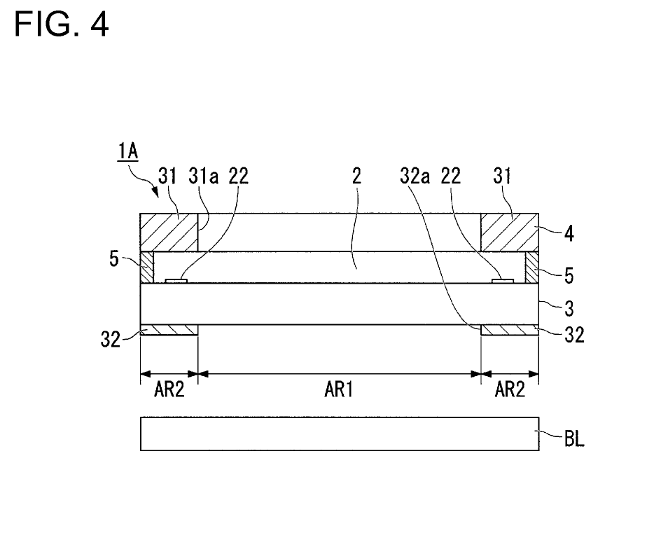

FIG. 4 is a cross-sectional view schematically showing a liquid crystal display panel 1A according to Embodiment 1.

Note that the liquid crystal display panel 1A shown in FIG. 4 has a structure that is basically identical to the structure of the liquid crystal display panel 1 described above. For this reason, descriptions of identical portions will be omitted, and will be given identical reference characters in diagrams.

In the liquid crystal display panel 1A according to Embodiment 1, a first light-shielding layer 31, which shields the peripheral region AR2 from light, is formed on the aforementioned opposite substrate 4. Specifically, the aforementioned black matrix layer can be used to form the first light-shielding layer 31 that covers a region corresponding to the peripheral region AR2 and that has an opening 31a in a region corresponding to the aforementioned display region AR1, if the first light-shielding layer 31 is to be provided on the surface of the opposite substrate 4 facing the liquid crystal layer 2.

Meanwhile, the first light-shielding layer 31 can also be provided on a side opposite to the surface of the opposite substrate 4 facing the liquid crystal layer 2. In this case, the same material as the one used for the aforementioned black matrix layer can be used to form the first light-shielding layer 31 that covers the region corresponding to the peripheral region AR2 and that has the opening 31a in the region corresponding to the display region AR1. In addition, it is also possible to dispose a frame-like member or the like forming the first light-shielding layer 31 on the surface of the opposite substrate 4 on the side opposite to the surface facing the liquid crystal layer 2.

Additionally, on a surface of the circuit substrate 3 of the liquid crystal display panel 1A that is on a side opposite to the surface facing the liquid crystal layer 2, a second light-shielding layer 32 is formed to shield the peripheral region AR2 from light. Specifically, the second light-shielding layer 32 is a coating film made of a photosensitive resin composition that covers the region corresponding to the peripheral region AR2 and that has an opening 32a in a region corresponding to the display region AR1.

The second light-shielding layer 32 is provided selectively in the region corresponding to the peripheral region AR2 in steps of manufacturing, which will be described later. Additionally, the opening 32a of the second light-shielding layer 32 has a shape that matches the opening 31a of the first light-shielding layer 31 in plan view.

(Liquid Crystal Display Device)

A light-transmissive liquid crystal display device is schematically configured by combining the liquid crystal display panel 1A, a backlight BL, a pair of polarizing plates (not shown in diagrams), and the like. Additionally, the backlight BL is disposed on a side opposite to the surface of the circuit substrate 3 that faces the liquid crystal layer 2.

In the liquid crystal display device with a structure such as the one described above, it is possible to see images displayed on the liquid crystal display panel 1A from the side of the opposite substrate 3 by illuminating the liquid crystal display panel 1A with light emitted by the backlight BL.

In the liquid crystal display panel 1A according to Embodiment 1, it is possible to block light entering the TFTs 22 for the peripheral circuit region from the side of the opposite substrate 4 using the first light-shielding layer 31 while blocking light entering the TFTs 22 for the peripheral circuit region from the side of the circuit substrate 3 using the second light-shielding layer 32. As a result, with respect to the liquid crystal display panel 1A, it is possible to prevent degradation of properties of the TFTs 22 for the peripheral circuit region by providing the TFTs 22 with an enhanced light-shielding effect.

(Method of Manufacturing Liquid Crystal Display Panel)

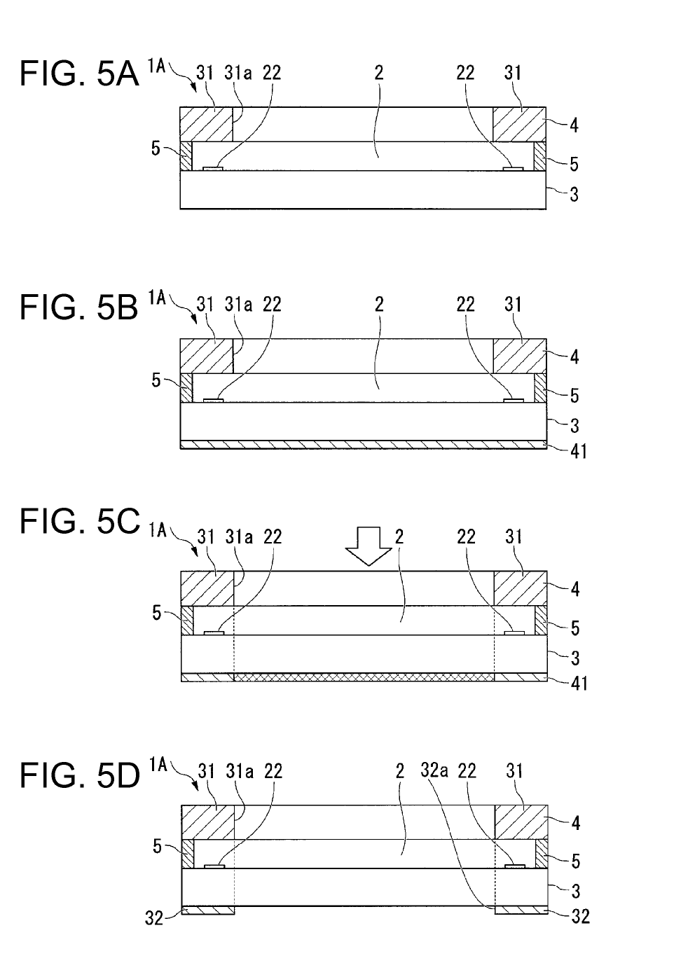

FIGS. 5A to 5D are cross-sectional views for describing steps of manufacturing the liquid crystal display panel 1A.

To manufacture the liquid crystal display panel 1A, the liquid crystal display panel 1A without the second light-shielding layer 32 is prepared first, as shown in FIG. 5A. Note that the first light-shielding layer 31 is arranged in the liquid crystal display panel 1A.

Next, a coating film 41 is formed using a photosensitive resin composition on a surface of the circuit substrate 3 on a side opposite to the surface facing the liquid crystal layer 4, as shown in FIG. 5B. For the photosensitive resin composition, materials such as those commonly used for a black matrix formed on the color filter substrate of a liquid crystal display panel can be used. Examples of such materials include a positive-type photosensitive resin in which black pigments such as carbon particulates are scattered.

Then, as shown in FIG. 5C, the coating film 41 is patterned into a shape corresponding to the first light-shielding layer 31 by exposing the coating film 41 to light radiated from the side of the opposite substrate 4 for photosensitization. At this time, the region of the coating film 41 corresponding to the display region AL1 is exposed to light through the opening 31a formed in the first light-shielding layer 31.

Next, as shown in FIG. 5D, by developing the coating film 41, the area of the coating film 41 exposed to light is selectively removed.

Thus, by following the steps described above, it is possible to form the second light-shielding layer 32 that covers the region corresponding to the peripheral region AR2 and has the opening 32a corresponding to the display region AR1. Here, the opening 32a corresponds to the portion of the coating film 41 that was selectively removed, while the second light-shielding layer 32 corresponds to the portion of the coating film 41 that was not selectively removed.

In the above method of manufacturing the liquid crystal display panel 1A, the coating film 41 is exposed to light and patterned using the first light-shielding layer 32 as a mask. As a result, it is possible to match the shape of the opening 32a formed in the second light-shielding layer 32 and the shape of the opening 32a formed in the first light-shielding layer 32 with good precision.

As such, according to the present method of manufacturing, it is possible to manufacture the liquid crystal display panel 1A, in which the second light-shielding layer 32 is provided with good precision to shield the TFTs 22 for the peripheral circuit region from light, with high yield and low cost.

### Embodiment 2

### Liquid Crystal Display Panel

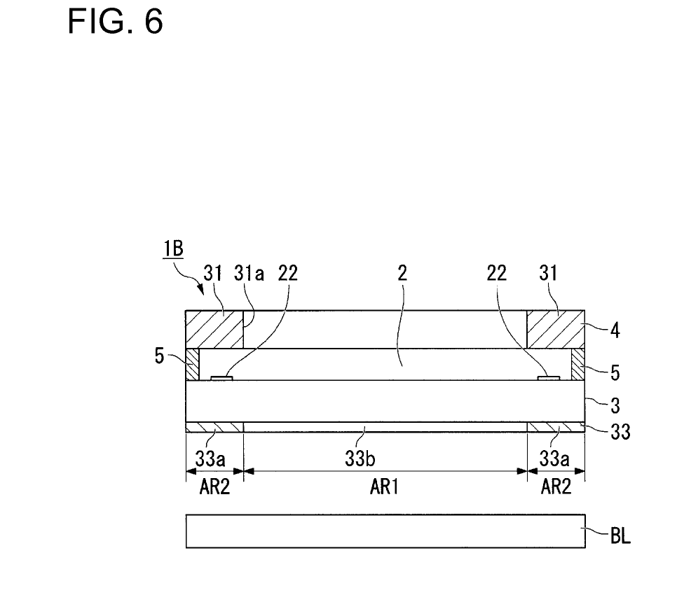

FIG. 6 is a cross-sectional view schematically showing a liquid crystal display panel 1B according to Embodiment 2.

Note that the liquid crystal display panel 1B shown in FIG. 6 has a structure that is basically identical to the structure of the liquid crystal display panel 1 described above. For this reason, descriptions of identical portions will be omitted, and will be given identical reference characters in diagrams.

In the liquid crystal display panel 1B according to Embodiment 2, a first light-shielding layer 31, which shields the peripheral region AR2 from light, is formed on the aforementioned opposite substrate 4. Specifically, the black matrix layer can be used to form the first light-shielding layer 31 that covers a region corresponding to the peripheral region AR2 and has an opening 31a in a region corresponding to the aforementioned display region AR1, if the first light-shielding layer 31 is to be provided on the surface of the opposite substrate 4 facing the liquid crystal layer 2.

Meanwhile, the first light-shielding layer 31 can also be provided on a side opposite to the surface of the opposite substrate 4 facing the liquid crystal layer 2. In this case, the same material as the one used for the aforementioned black matrix layer can be used to form the first light-shielding layer 31 that covers the region corresponding to the peripheral region AR2 and has the opening 31a in the region corresponding to the display region AR1. In addition, it is also possible to dispose a frame-like member or the like forming the first light-shielding layer 31 on the surface of the opposite substrate 4 on the side opposite to the surface facing the liquid crystal layer 2.

Additionally, on a surface of the circuit substrate 3 of the liquid crystal display panel 1B that is on a side opposite to the surface facing the liquid crystal layer 2, a second light-shielding layer 33 is formed to shield the peripheral region AR2 from light. Specifically, the second light-shielding layer 33 is a coating film made of a photosensitive resin composition that has a light-shielding portion 33a covering a region corresponding to the peripheral region AR2 and a light-transmissive portion 33b covering a region corresponding to the display region AR1.

Of these, the light-shielding portion 33a is a portion of the photosensitive resin composition that has remained without being decolorized. In contrast, the light-transmissive portion 33b is a decolorized portion of the photosensitive resin composition having a light-transmissive property (transparent portion). In other words, the second light-shielding layer 33 is a coating film having a light-shielding property, a portion of which is selectively decolorized in steps of manufacturing, which will be described later. Further, the light-transmissive portion 33b of the second light-shielding layer 32 has a shape that matches the opening 31a of the first light-shielding layer 31 in plan view.

(Liquid Crystal Display Device)

A light-transmissive liquid crystal display device is schematically configured by combining the liquid crystal display panel 1B, a backlight BL, a pair of polarizing plates (not shown in diagrams), and the like. Additionally, the backlight BL is disposed on a side opposite to the surface of the circuit substrate 3 that faces the liquid crystal layer 2.

In the liquid crystal display device with a structure such as the one described above, it is possible to see images displayed on the liquid crystal display panel 1B from the side of the opposite substrate 3 by illuminating the liquid crystal display panel 1B with light emitted by the backlight BL.

In the liquid crystal display panel 1B according to Embodiment 2, it is possible to block light entering the TFTs 22 for the peripheral circuit region from the side of the opposite substrate 4 using the first light-shielding layer 31 while blocking light entering the TFTs 22 for the peripheral circuit region from the side of the circuit substrate 3 using the light-shielding portion 33a of the second light-shielding layer 33. As a result, with respect to the liquid crystal display panel 1B, it is possible to prevent degradation of properties of the TFTs 22 for the peripheral circuit region by providing the TFTs 22 with an enhanced light-shielding effect.

(Method of Manufacturing Liquid Crystal Display Panel)

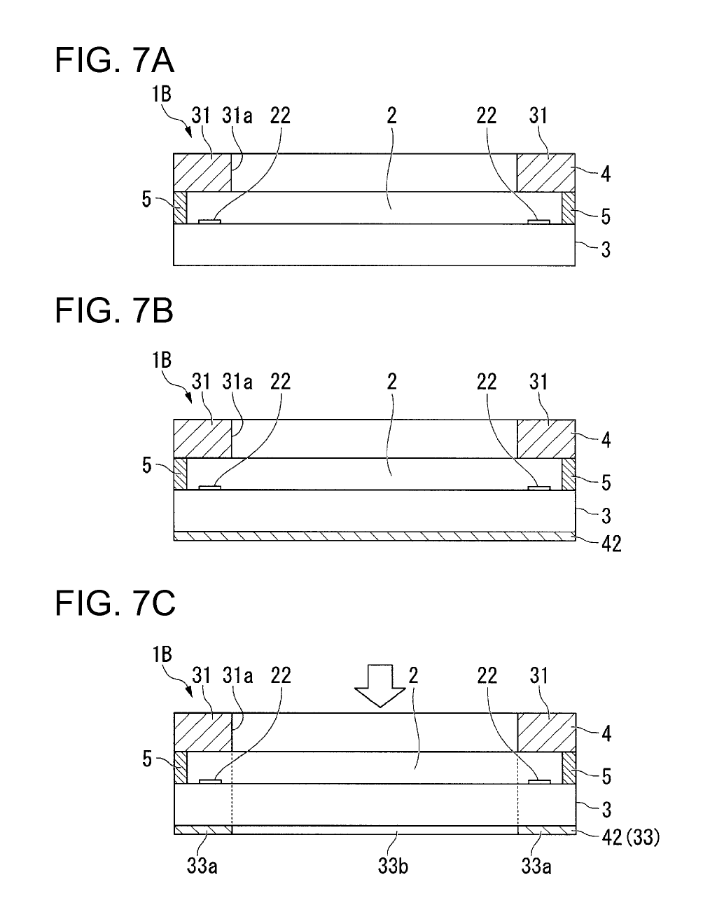

FIGS. 7A to 7C are cross-sectional views for describing steps of manufacturing the liquid crystal display panel 1B.

To manufacture the liquid crystal display panel 1B, the liquid crystal display panel 1B without the second light-shielding layer 33 is prepared first, as shown in FIG. 7A. Note that the first light-shielding layer 31 is arranged in the liquid crystal display panel 1B.

Next, a coating film 42 is formed using a photosensitive resin composition on a surface of the circuit substrate 3 on a side opposite to the surface facing the liquid crystal layer 4, as shown in FIG. 7B. For the photosensitive resin composition, a general photosensitive resin well known for having a decolorizing property when exposed by light can be used.

Then, as shown in FIG. 7C, the coating film 42 is patterned into a shape corresponding to the first light-shielding layer 31 by exposing the coating film 42 to light radiated from the side of the opposite substrate 4 for photosensitization. At this time, the region of the coating film 42 corresponding to the display region AL1 is exposed to light through the opening 31a formed in the first light-shielding layer 31.

At this time, the portion of the coating film 42 that has been exposed to light becomes a light-transmissive portion 33b having a light-transmissive property when the photosensitive resin composition is eventually decolorized. In contrast, the portion of the coating film 42 that was not exposed to light becomes a light-shielding portion 33a having a light-shielding property, since the photosensitive resin composition remains without being decolorized.

Thus, by following the steps described above, it is possible to form the second light-shielding layer 33 having the light-shielding portion 33a that covers the region corresponding to the peripheral region AR2 and the light-transmissive portion 33b that covers the region corresponding to the display region AR1.

In the above method of manufacturing the liquid crystal display panel 1B, the coating film 42 is exposed to light and patterned using the first light-shielding layer 32 as a mask. As a result, it is possible to match the shape of the light-transmissive portion 33b formed in the second light-shielding layer 33 and the shape of the opening 32a formed in the first light-shielding layer 32 with good precision.

As such, according to the present method of manufacturing, it is possible to manufacture the liquid crystal display panel 1B, in which the second light-shielding layer 33 is provided with good precision to shield the TFTs 22 for the peripheral circuit region from light, with high yield and low cost.

### Embodiment 3

### Liquid Crystal Display Panel

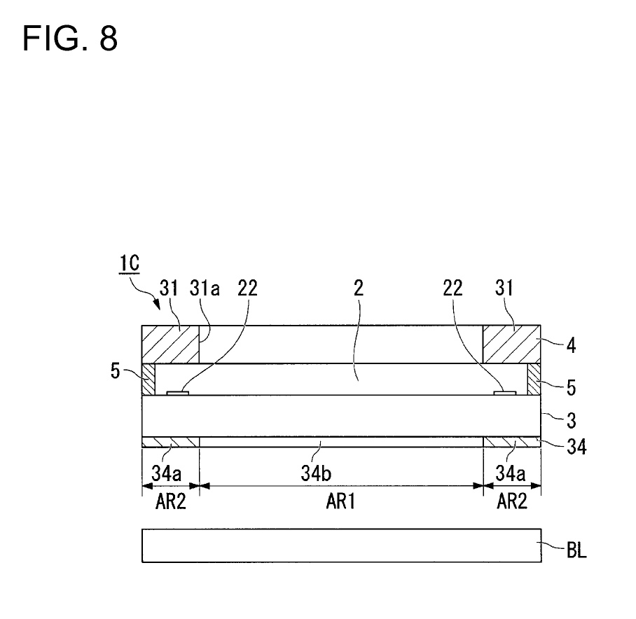

FIG. 8 is a cross-sectional view schematically showing a liquid crystal display panel 1C according to Embodiment 3.

Note that the liquid crystal display panel 1C shown in FIG. 8 has a structure that is basically identical to the structure of the liquid crystal display panel 1 described above. For this reason, descriptions of identical portions will be omitted, and will be given identical reference characters in diagrams.

In the liquid crystal display panel 1C according to Embodiment 3, a first light-shielding layer 31, which shields the peripheral region AR2 from light, is formed on the aforementioned opposite substrate 4. Specifically, the black matrix layer can be used to form the first light-shielding layer 31 that covers a region corresponding to the peripheral region AR2 and has an opening 31a in a region corresponding to the aforementioned display region AR1, if the first light-shielding layer 31 is to be provided on the surface of the opposite substrate 4 facing the liquid crystal layer 2.

Meanwhile, the first light-shielding layer 31 can also be provided on a side opposite to the surface of the opposite substrate 4 facing the liquid crystal layer 2. In this case, the same material as the one used for the aforementioned black matrix layer can be used to form the first light-shielding layer 31 that covers the region corresponding to the peripheral region AR2 and has the opening 31a in the region corresponding to the display region AR1. In addition, it is also possible to dispose a frame-like member or the like forming the first light-shielding layer 31 on the surface of the opposite substrate 4 on the side opposite to the surface facing the liquid crystal layer 2.

Additionally, on a surface of the circuit substrate 3 of the liquid crystal display panel 1C that is on a side opposite to the surface facing the liquid crystal layer 2, a second light-shielding layer 34 is formed to shield the peripheral region AR2 from light. Specifically, the second light-shielding layer 34 is a coating film made of a photosensitive resin composition that has a light-shielding portion 34a covering a region corresponding to the peripheral region AR2 and a light-transmissive portion 34b covering a region corresponding to the display region AR1.

Of these, the light-shielding portion 34a is a portion having a light-shielding property as a result of the coloration of the photosensitive resin composition. In contrast, the light-transmissive portion 33b is a portion of the photosensitive resin composition remaining as is without being colorized (transparent portion). In other words, the second light-shielding layer 34 is a coating film having a light-transmissive property, a portion of which is selectively colorized in steps of manufacturing, which will be described later. Further, the light-transmissive portion 34b of the second light-shielding layer 34 has a shape that matches the opening 31a of the first light-shielding layer 31 in plan view.

(Liquid Crystal Display Device)

A light-transmissive liquid crystal display device is schematically configured by combining the liquid crystal display panel 1C, a backlight BL, a pair of polarizing plates (not shown in diagrams), and the like. Additionally, the backlight BL is disposed on a side opposite to the surface of the circuit substrate 3 that faces the liquid crystal layer 2.

In the liquid crystal display device with a structure such as the one described above, it is possible to see images displayed on the liquid crystal display panel 1C from the side of the opposite substrate 3 by illuminating the liquid crystal display panel 1C with light emitted by the backlight BL.

In the liquid crystal display panel 1C according to Embodiment 2, it is possible to block light entering the TFTs 22 for the peripheral circuit region from the side of the opposite substrate 4 using the first light-shielding layer 31 while blocking light entering the TFTs 22 for the peripheral circuit region from the side of the circuit substrate 3 using the light-shielding portion 34a of the second light-shielding layer 34. As a result, with respect to the liquid crystal display panel 1C, it is possible to prevent degradation of properties of the TFTs 22 for the peripheral circuit region by providing the TFTs 22 with an enhanced light-shielding effect.

(Method of Manufacturing Liquid Crystal Display Panel)

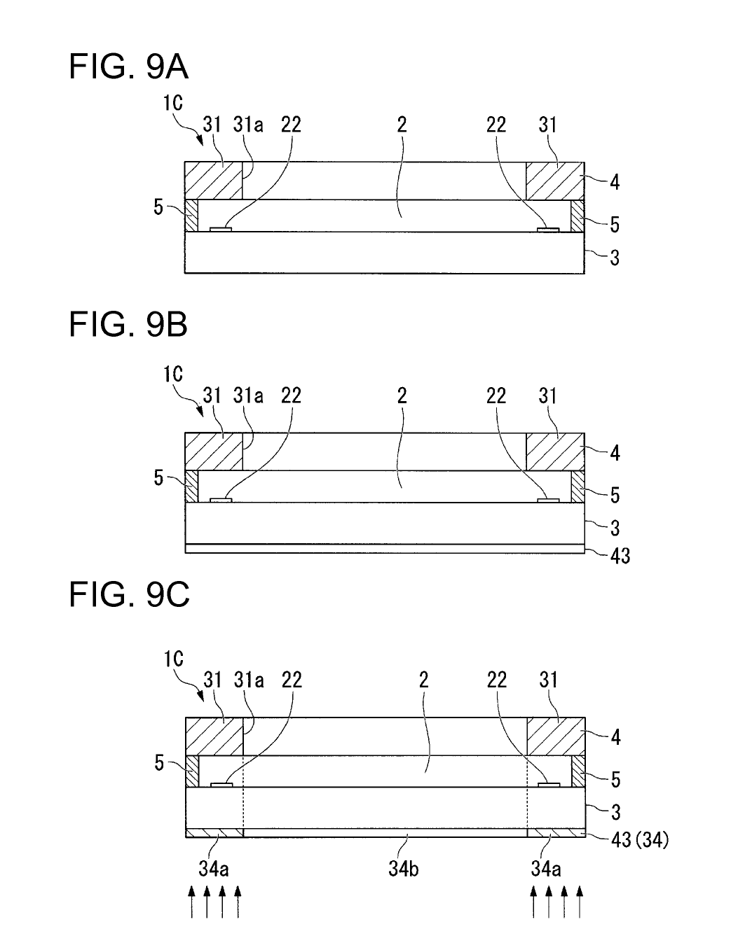

FIGS. 9A to 9C are cross-sectional views for describing steps of manufacturing the liquid crystal display panel 1C.

To manufacture the liquid crystal display panel 1C, the liquid crystal display panel 1C without the second light-shielding layer 34 is prepared first, as shown in FIG. 9A. Note that the first light-shielding layer 31 is arranged in the liquid crystal display panel 1C.

Next, a coating film 43 is formed using a photosensitive resin composition on a surface of the circuit substrate 3 on a side opposite to the surface facing the liquid crystal layer 4, as shown in FIG. 9B. For the photosensitive resin composition, a general photosensitive resin well known for having a coloring property when exposed by light can be used.

Then, as shown in FIG. 9C, the coating film 43 is patterned into a shape corresponding to the peripheral region AR2 by exposing the coating film 43 to light radiated from the side of the circuit substrate 3 for photosensitization. At this time, the region of the coating film 43 corresponding to the peripheral region AR2 is selectively exposed to light.

As a result, the portion of the coating film 43 that has been exposed to light becomes a light-shielding portion 34a having a light-shielding property when the photosensitive resin composition is eventually colorized. In contrast, the portion of the coating film 43 that was not exposed to light becomes a light-transmissive portion 34b having a light-shielding property, since the photosensitive resin composition remains without being colorized.

Thus, by following the steps described above, it is possible to form the second light-shielding layer 34 having a light-shielding portion 34a that covers the region corresponding to the peripheral region AR2 and a light-transmissive portion 34b that covers the region corresponding to the display region AR1.

In the above method of manufacturing the liquid crystal display panel 1C, the portion of the coating film 43 corresponding to the peripheral region AR2 is illuminated with light from the side of the circuit substrate 3. As a result, it is possible to match the shape of the light-shielding portion 34a formed in the second light-shielding layer 34 and the shape of the peripheral region AR2 with good precision.

As such, according to the present method of manufacturing, it is possible to manufacture the liquid crystal display panel 1C, in which the second light-shielding layer 34 is provided with good precision to shield the TFTs 22 for the peripheral circuit region from light, with high yield and low cost.

### INDUSTRIAL APPLICABILITY

The present invention is applicable to a liquid crystal display panel, a liquid crystal display device, and a method of manufacturing a liquid crystal display panel, which require an enhanced light-shielding effect for thin film transistors provided in the peripheral circuit region.

### DESCRIPTION OF REFERENCE CHARACTERS

1, 1A, 1B, 1C liquid crystal display panel
2 liquid crystal layer
3 circuit substrate (first transparent substrate)
4 opposite substrate (second transparent substrate)
5 sealing member
6 switching element (thin film transistor)
7 source driver (peripheral circuit region)
8 gate driver (peripheral circuit region)
10 terminal
14 semiconductor layer
14s first heavily doped region (source region)
14c channel region
14d second heavily doped region (drain region)
18 second interlayer insulating film (organic insulating film)
19 second passivation film (inorganic insulating film)
20 common electrode
21 pixel electrode
22 thin film transistor
31 first light-shielding layer
32, 33, 34 second light-shielding layer
41, 42, 43 coating film
AR1 display region
AR2 peripheral region
AR3 terminal-forming region (region in which a plurality of terminals are formed)

1. A liquid crystal display panel, comprising:
a first transparent substrate and a second transparent substrate facing each other;
a liquid crystal layer sandwiched between said first transparent substrate and said second transparent substrate;
a display region provided on a surface of said first transparent substrate facing said liquid crystal layer and having at least a plurality of pixel electrodes;
a peripheral circuit region provided around said display region and having at least a plurality of thin film transistors;
a first light-shielding layer provided on a side of said second transparent substrate so as to shield at least a region corresponding to said peripheral circuit region from light; and
a second light-shielding layer provided on a surface of said first transparent substrate on a side opposite to the surface facing said liquid crystal layer so as to shield at least a region corresponding to said peripheral circuit region from light.

2. The liquid crystal display panel according to claim 1, wherein said second light-shielding layer is made of a photosensitive resin composition selectively provided in at least the region corresponding to said peripheral circuit region.

3. The liquid crystal display panel according to claim 1, wherein said second light-shielding layer is made of a photosensitive resin composition that covers the surface of said first transparent substrate on the side opposite to the surface facing said liquid crystal layer and that is selectively decolorized in at least a region corresponding to the display region.

4. The liquid crystal display panel according to claim 1, wherein said second light-shielding layer is made of a photosensitive resin composition that covers the surface of said first transparent substrate facing said liquid crystal layer and that is selectively colorized in at least a region corresponding to said peripheral circuit region.

5. The liquid crystal display panel according to claim 1, wherein thin film transistors respectively made of oxide semiconductors are provided in said peripheral circuit region.

6. A liquid crystal display device, comprising:
the liquid crystal display panel according to claim 1; and
a backlight that illuminates said liquid crystal display panel.

7. The liquid crystal display device according to claim 6, wherein said backlight is disposed on the side opposite to the surface of said first transparent substrate facing said liquid crystal layer.

8. A method of manufacturing a liquid crystal display panel, comprising:
preparing a liquid crystal display panel that includes a first transparent substrate and a second transparent substrate facing each other; a liquid crystal layer sandwiched between said first transparent substrate and said second transparent substrate; a display region provided on a surface of said first transparent substrate facing said liquid crystal layer and having at least a plurality of pixel electrodes; a peripheral circuit region provided around said display region and having at least a plurality of thin film transistors; a first light-shielding layer provided on a side of said second transparent substrate so as to shield at least a region corresponding to said peripheral circuit region from light; and
forming a second light-shielding layer provided on a side of said first transparent substrate so as to shield at least a region corresponding to said peripheral circuit region from light,
wherein the step of forming said second light-shielding layer further comprises:
forming a coating film of a photosensitive resin composition on a surface of said first transparent substrate on a side opposite to the surface facing said liquid crystal layer; and
patterning said coating film into a shape corresponding to said first light-shielding layer by exposing said coating film to light radiated from a side of said second transparent substrate.

9. The method of manufacturing a liquid crystal display panel according to claim 8, further comprising selectively removing a portion of said coating film that has been patterned by exposure to light.

10. The method of manufacturing a liquid crystal display panel according to claim 8, wherein a photosensitive resin composition is used in which portions thereof exposed to light are decolorized.

11. A method of manufacturing a liquid crystal display panel, comprising:
preparing a liquid crystal display panel that includes a first transparent substrate and a second transparent substrate facing each other; a liquid crystal layer sandwiched between said first transparent substrate and said second transparent substrate; a display region provided on a surface of said first transparent substrate facing said liquid crystal layer and having at least a plurality of pixel electrodes; a peripheral circuit region provided around said display region and having at least a plurality of thin film transistors; a first light-shielding layer provided on a side of said second transparent substrate so as to shield at least a region corresponding to said peripheral circuit region from light; and
forming a second light-shielding layer provided on a side of said first transparent substrate so as to shield at least a region corresponding to said peripheral circuit region from light,
wherein the step of forming said second light-shielding layer further comprises:
forming a coating film of a photosensitive resin composition on a surface of said first transparent substrate on a side opposite to the surface facing said liquid crystal layer; and
patterning said coating film into a shape corresponding to said peripheral circuit region by exposing said coating film to light radiated from a side of first transparent substrate.

12. The method of manufacturing a liquid crystal display panel according to claim 11, wherein a photosensitive resin composition is used in which portions thereof exposed to light are decolorized.

13. The method of manufacturing a liquid crystal display panel according to claim 8, wherein thin film transistors respectively made of oxide semiconductors are provided in said peripheral circuit region.

14. The method of manufacturing a liquid crystal display panel according to claim 11, wherein thin film transistors respectively made of oxide semiconductors are provided in said peripheral circuit region.
